(19) United States
(12) Patent Application Publication
(10) Pub. No.: US 2019/0355792 A1
(43) Pub. Date: Nov. 21, 2019

(54) PIXEL STRUCTURES, MASKS, AND DISPLAY DEVICES

(71) Applicant: KUNSHAN GO-VISIONOX OPTO-ELECTRONICS CO., LTD., Kunshan (CN)

(72) Inventors: Jun YU, Kunshan (CN); Xiaoxu HU, Kunshan (CN); Xin YE, Kunshan (CN); Hui ZHU, Kunshan (CN); Xiujian ZHU, Kunshan (CN)

(73) Assignee: KUNSHAN GO-VISIONOX OPTO-ELECTRONICS CO., LTD., Kunshan (CN)

(21) Appl. No.: 16/531,417

(22) Filed: Aug. 5, 2019

Related U.S. Application Data
(63) Continuation of application No. PCT/CN2018/090236, filed on Jun. 7, 2018.

(30) Foreign Application Priority Data
Aug. 31, 2017 (CN) 201710776292.1

(51) Int. Cl. H01L 27/32

(52) U.S. Cl. CPC H01L 27/3213; H01L 27/3218; G09G 3/20; G09G 2300/0465; G09G 2300/0452

(57) ABSTRACT

A pixel structure, a mask, and a display device. In the pixel structure, each pixel group includes four sub-pixel groups with different colors. The four sub-pixel groups have different colors from each other. Not all of the four sub-pixel groups include an identical number of sub-pixels. And each sub-pixel in a sub-pixel group having a minimum number of sub-pixels is shared.

### FIELD

The present disclosure relates to the field of display technologies.

### BACKGROUND

Organic Light-Emitting Diode (OLED) display technology has a self-illuminating characteristic, uses a rather thin organic coating and has advantages of a large viewing angle of a display screen and energy saving, thus being widely applied in a product such as mobile phone, digital video camera, DVD player, Personal Digital Assistant (PDA), notebook computer, car stereo, television and so on.

### SUMMARY

Exemplary embodiments of the present disclosure provide pixel structures, masks, and display devices, which can widen the color gamut and enhance the PPI, thereby achieving a better display effect.

An exemplary embodiment of the present disclosure provides a pixel structure, including a plurality of pixel groups, wherein each pixel group includes four sub-pixel groups having different colors from each other, not all of the four sub-pixel groups including an identical number of sub-pixels, and each sub-pixel of a sub-pixel group having a minimum number of sub-pixels is shared.

Optionally, the four sub-pixel groups in each pixel group are classified into a first-type sub-pixel group and a second-type sub-pixel group depending on the number of sub-pixels of each sub-pixel group, wherein the first-type sub-pixel group has a minimal number of sub-pixels, which is one or two, and the sub-pixels in the first-type sub-pixel groups are arranged in a same manner; wherein a number of the sub-pixels in the second-type sub-pixel group is twice a number of the sub-pixels in the first-type sub-pixel group, and the sub-pixels in the second-type sub-pixel groups are arranged in a same manner.

Optionally, all of the sub-pixels in the first-type sub-pixel group are identical in shape and size, and all of the sub-pixels in the second-type sub-pixel group are identical in shape and size.

Optionally, each of the sub-pixels in each pixel group has a shape of a rectangle; a width of a rectangle of a sub-pixel in the first-type sub-pixel group is equal to a width of a rectangle of a sub-pixel in the second-type sub-pixel group; and a length of a rectangle of a sub-pixel in the first-type sub-pixel group is equal to a sum of lengths of rectangles of two adjacent sub-pixels in the second-type sub-pixel group and a length of a gap between the two adjacent sub-pixels.

Optionally, colors of four sub-pixel groups in each pixel group are red, green, blue, and a fourth color, and the fourth color is a color different from red, green, and blue.

Optionally, in each pixel group, when each first-type sub-pixel group includes one sub-pixel, each second-type sub-pixel group includes two sub-pixels arranged in two rows and one column or two columns and one row, and the two sub-pixels in the second-type sub-pixel group are arranged along a length direction of the sub-pixel in the first-type sub-pixel group.

Optionally, in each pixel group, when each first-type sub-pixel group includes two sub-pixels, each second-type sub-pixel group includes four sub-pixels arranged in an array of two rows and two columns, and the two sub-pixels in the first-type sub-pixel group are arranged in two rows and one column or two columns and one row.

Optionally, two of the four sub-pixel groups in each pixel group are the first-type sub-pixel groups, and two first-type sub-pixel groups are arranged side by side or diagonally.

An exemplary embodiment of the present disclosure provides a mask for manufacturing any pixel structure described above.

Optionally, a size of one evaporation aperture of the mask corresponds to a sum of a size of at least two sub-pixels of a same color in a pixel group of the pixel structure having two or more sub-pixels.

An exemplary embodiment of the present disclosure provides a display device, including any pixel structure described above.

The technical solutions of the present disclosure have the following advantageous effects:

1. Each pixel group includes four sub-pixel groups of different colors, enabling to enhance the luminosity, reduce the power consumption, as well as enlarge the color gamut and display colors of a natural image better.

2. At least two sub-pixels of a same color in each sub-pixel group having two or more sub-pixels are able to share one evaporation aperture, thereby enabling to reduce spatial occupation, lower the difficulty in manufacturing masks, and facilitate achievement of a high PPI.

3. Not all of the four sub-pixel groups in each pixel group include an identical number of sub-pixels, and each sub-pixel of a sub-pixel group having a minimum number of sub-pixels is shared, thereby enabling to achieve a high PPI.

### BRIEF DESCRIPTION OF THE DRAWINGS

FIG. 1 is a schematic arrangement diagram of a pixel structure of an OLED display panel;

FIG. 2A is schematic diagram of a pixel structure according to an exemplary embodiment of the present disclosure;

FIG. 2B is schematic diagram of a pixel structure according to an exemplary embodiment of the present disclosure;

FIG. 3A is schematic diagram of an alternative pixel structure according to an exemplary embodiment of the present disclosure;

FIG. 3B is schematic diagram of an alternative pixel structure according to an exemplary embodiment of the present disclosure;

FIG. 4A is schematic diagram of an alternative pixel structure according to an exemplary embodiment of the present disclosure;

FIG. 4B is schematic diagram of an alternative pixel structure according to an exemplary embodiment of the present disclosure;

FIG. 5A is schematic diagram of an alternative pixel structure according to an exemplary embodiment of the present disclosure;

FIG. 5B is schematic diagram of an alternative pixel structure according to an exemplary embodiment of the present disclosure;

FIG. 6A is schematic diagram of an alternative pixel structure according to an exemplary embodiment of the present disclosure;

FIG. 6B is schematic diagram of an alternative pixel structure according to an exemplary embodiment of the present disclosure;

FIG. 7A is schematic diagram of an alternative pixel structure according to an exemplary embodiment of the present disclosure;

FIG. 7B is schematic diagram of an alternative pixel structure according to an exemplary embodiment of the present disclosure;

FIG. 8A is schematic diagram of a mask according to an exemplary embodiment of the present disclosure;

FIG. 8B is schematic diagram of a mask according to an exemplary embodiment of the present disclosure;

FIG. 9A is schematic diagram of evaporation aperture of a mask according to an exemplary embodiment of the present disclosure;

FIG. 9B is schematic diagram of evaporation aperture of a mask according to an exemplary embodiment of the present disclosure;

FIG. 9C is schematic diagram of evaporation aperture of a mask according to an exemplary embodiment of the present disclosure;

FIG. 9D is schematic diagram of evaporation aperture of a mask according to an exemplary embodiment of the present disclosure;

FIG. 9E is schematic diagram of evaporation aperture of a mask according to an exemplary embodiment of the present disclosure;

FIG. 10A is schematic arrangement diagram of four sub-pixel groups of a pixel group according to an exemplary embodiment of the present disclosure;

FIG. 10B is schematic arrangement diagram of four sub-pixel groups of a pixel group according to an exemplary embodiment of the present disclosure;

FIG. 10C is schematic arrangement diagram of four sub-pixel groups of a pixel group according to an exemplary embodiment of the present disclosure;

FIG. 10D is schematic arrangement diagram of four sub-pixel groups of a pixel group according to an exemplary embodiment of the present disclosure;

FIG. 10E is schematic arrangement diagram of four sub-pixel groups of a pixel group according to an exemplary embodiment of the present disclosure; and

FIG. 10F is schematic arrangement diagram of four sub-pixel groups of a pixel group according to an exemplary embodiment of the present disclosure.

### DETAILED DESCRIPTION

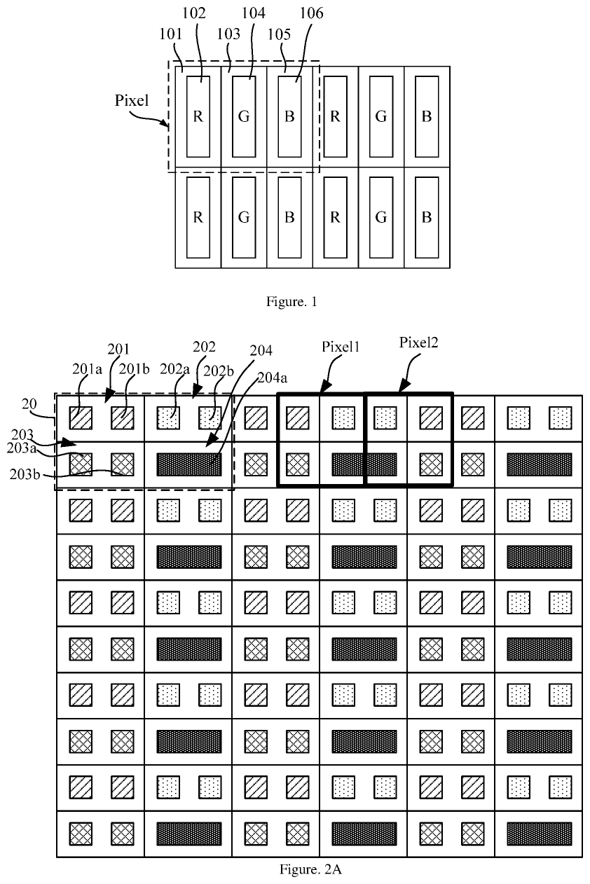

A side-by-side arrangement of a pixel is used in a typical pixel structure of an OLED display panel. In the side-by-side method, there are three sub-pixels, i.e. Red, Green, and Blue (R, G, B) sub-pixels in the range of one Pixel. Each sub-pixel is rectangular, and has an independent organic light-emitting component. Specifically, as shown in FIG. 1, each pixel unit includes an R (red) sub-pixel 101, a G (green) sub-pixel 103, and a B (blue) sub-pixel 105, arranged in a straight line. The R, G, B sub-pixels are all rectangular, all sub-pixels are equal in size, and the ratio of the numbers of the R, G, B sub-pixels is 1:1:1. Such pixel structure is generally called Real RGB in industry. Generally, the realization of such pixel structure needs to use evaporation film forming technology. Films of corresponding colors are evaporated at corresponding pixel positions of an array substrate through evaporation openings of a Fine Metal Mask (FMM), to form sub-pixels of corresponding colors. The FMM is usually referred to as an evaporation mask.

In the foregoing pixel structure, the pixel units produce a large pixel area. In the case where the total area of an OLED display panel is fixed, a larger pixel area results in a fewer number of pixels, inevitably limiting the enhancement of the Pixel Per Inch (PPI). Besides, the FMM generally has a limitation of a minimum opening. The sub-pixels of different colors in the evaporation process have a spacing limitation between the openings. The preparation of the OLED pixel structure is inevitably limited by the FMM opening and the precision of the evaporation process. When the PPI is higher than 300 PPI, it is rather difficult for the existing FMM process to arrange three sub-pixels of RGB in one pixel range of the foregoing OLED pixel structure. In addition, the foregoing pixel structure has only three colors with a relatively narrow color gamut, failing to reproduce bright and unsaturated colors and meet the development requirement of a better display of colors of natural images.

Pure red, green, and blue colors are rare in the colors existed in the nature. Most of the colors are complementary colors to the three primary colors of red, green and blue, i.e. cyan, magenta (purple), yellow, and mixed colors thereof (also known as intermediate colors). Among these colors, cyan accounts for a big part. In the conventional RGB pixel structure, in order to vividly display the intermediate color (yellow, cyan or magenta), the luminosity and brightness of the light source need to be dramatically enhanced, thereby increasing the power consumption. That is, the conventional RGB pixel structure fails to achieve a better display effect and lower power consumption of products.

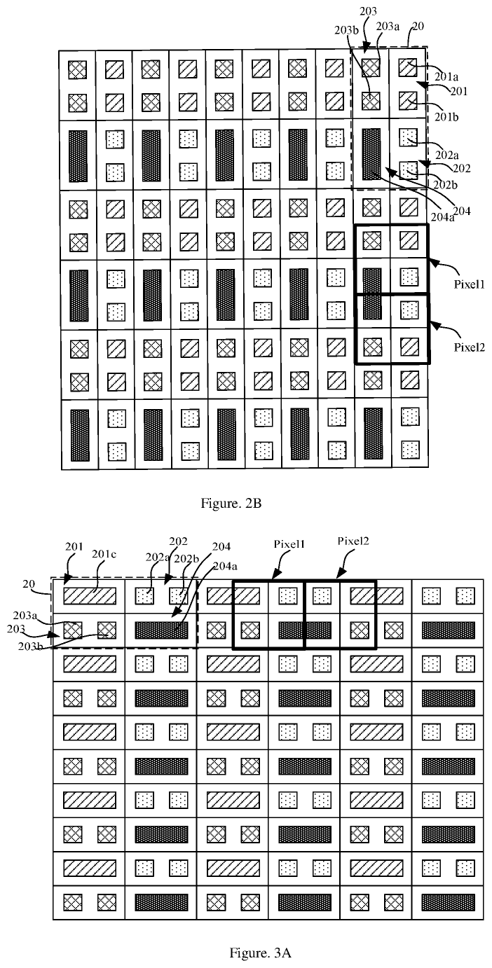

Referring to FIG. 2A, an exemplary embodiment of the present disclosure provides a pixel structure, including a plurality of pixels groups 20 arranged in an array. Each pixel group 20 includes four sub-pixel groups, i.e., a first sub-pixel group 201, a second sub-pixel group 202, a third sub-pixel group 203, and a fourth sub-pixel group 204, which have different colors and are arranged in an array of two rows and two columns Not all of the four sub-pixel groups in each pixel group include an identical number of sub-pixels. Each sub-pixels of a sub-pixel group having a minimum number of sub-pixels is shared. The sharing of the sub-pixel is able to enhance the aperture ratio of the shared sub-pixel, prolonging the service life of a product.

Preferably, the four colors are red (R), green (G), blue (B), and a fourth color, in which is the fourth color is a color different from red, green, and blue, such as cyan, yellow, dark red, magenta (also referred to as purple), or white. For example, the color of the first sub-pixel group 201 is red (R), the color of the second sub-pixel group 202 is green (G), the color of the third sub-pixel group 203 is the fourth color, and the color of the fourth sub-pixel group 204 is blue (B). The addition of the fourth color changes the color gamut figure from an original triangular shape to a quadrangular shape, thereby enabling to widen the color gamut as well as reduce the power consumption due to the display of an intermediate color without a dramatically enhanced luminosity and brightness of a light source. When the fourth color is cyan, the color reproduction capacity is able to be improved.

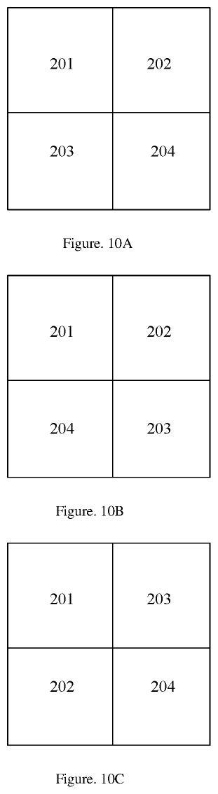

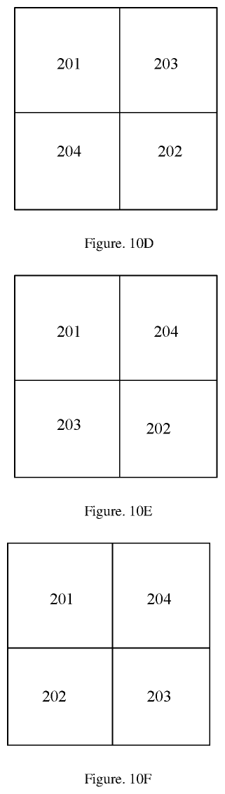

In addition, in this exemplary embodiment, the array of two rows and two columns formed by the four sub-pixel groups, i.e. the first sub-pixel group 201, the second sub-pixel group 202, the third sub-pixel group 203, and the fourth sub-pixel group 204,may be arranged in any array mode shown in FIG. 10A to FIG. 10E For example, the arrangement of the four sub-pixel groups in FIG. 2A uses the array mode shown in FIG. 10A.

In this exemplary embodiment, one of the four sub-pixel groups in each pixel group 20 has only one sub-pixel, each of the other three sub-pixel groups has two sub-pixels. The three sub-pixel groups each having two sub-pixels are identical in arrangement of sub-pixels. The four sub-pixel groups in each pixel group 20 may be classified into two types according to the number of sub-pixels in each sub-pixel group. The sub-pixel group having a minimal number of sub-pixels is defined as a first-type sub-pixel group; and each of the other three sub-pixel groups having sub-pixels twice as many as the number of sub-pixels in the first-type sub-pixel group is defined as a second-type sub-pixel group. Each of the sub-pixels in the first-type sub-pixel group is shared by two corresponding sub-pixels in the second-type sub-pixel group. For example, as shown in FIG. 2A, the fourth sub-pixel group 204 has only one fourth sub-pixel 204a. That is, the fourth sub-pixel group 204 has a minimal number of sub-pixels and belongs to the first-type sub-pixel group. However, the first sub-pixel group 201 has two first sub-pixels 201a and 201b; the second sub-pixel group 202 has two second sub-pixels 202a and 202b; and the third sub-pixel group 203 has two third sub-pixels 203a and 203b. That is, the number of sub-pixels in each of the first sub-pixel group 201, the second sub-pixel group 202, and the third sub-pixel group 203 is twice the number of sub-pixels in the fourth sub-pixel group 204. Therefore, the sub-pixel groups 201, 202, and 203 all belong to the second-type sub-pixel group. The first sub-pixels 201a and 201b and the second sub-pixels 202a and 202b are successively arranged in a row (that is, successively arranged in a horizontal direction), and the third sub-pixels 203a and 203b and the fourth sub-pixel 204a are arranged in another row (that is, successively arranged in a horizontal direction). Moreover, the fourth sub-pixel 204a is arranged below and shared by the second sub-pixels 202a and 202b. The sub-pixels in each of the second-type sub-pixel groups (i.e., the first sub-pixel group 201, the second sub-pixel group 202, and the third sub-pixel group 203) have a same arrangement. Specifically, the first sub-pixels 201a and 201b in the first sub-pixel group 201 are arranged in two columns and one row (or one row and two columns), the second sub-pixels 202a and 202b in the second sub-pixel group 202 are arranged also in two columns and one row (or one row and two columns), and the third sub-pixels 203a and 203b in the third sub-pixel group 203 are arranged also in two columns and one row (or one row and two columns). The fourth sub-pixel 204a in the fourth sub-pixel group 204 is horizontally elongated. The long side of the fourth sub-pixel 204a extends along an arrangement direction (that is, the horizontal direction or the row direction) of the second sub-pixels 202a and 202b in the second sub-pixel group 202 (which is in the same column with the fourth sub-pixel group 204); or in other words, the long side of the fourth sub-pixel 204a extends along an arrangement direction of the third sub-pixels 203a and 203b in the third sub-pixel group 203 (which is in the same row with the fourth sub-pixel group 204);or in other words, each of the second sub-pixels 202a and 202b and the third sub-pixels 203a and 203b are arranged along a length direction of the fourth sub-pixel 204a. That is, if each first-type sub-pixel group includes one sub-pixel, then each second-type sub-pixel group includes two sub-pixels arranged in two rows and one column or in two columns and one row, where the two sub-pixels are arranged along a length direction of the sub-pixel in the first-type sub-pixel group. Preferably, when each of the sub-pixels has a shape of a rectangle, the width of the rectangle corresponding to the fourth sub-pixel 204a is equal to the width of the rectangle corresponding to the second sub-pixel 202a, and the length of the rectangle corresponding to the fourth sub-pixel 204a is equal to the sum of the lengths of two rectangles corresponding to the two second sub-pixels 202a and 202b and the length of a gap between the two second sub-pixels 202a and 202b. That is, all of the sub-pixels in the first-type sub-pixel group are identical in shape and size, and all of the sub-pixels in the second-type sub-pixel group are identical in shape and size. Each of the sub-pixels has a shape of a rectangle. Moreover, the width of the rectangle corresponding to a sub-pixel in the first-type sub-pixel group is equal to the width of the rectangle corresponding to a sub-pixel in the second-type sub-pixel group; and the length of the rectangle corresponding to a sub-pixel in the first-type sub-pixel group is equal to the sum of lengths of two rectangles corresponding to two adjacent sub-pixels in the second-type sub-pixel group and the length of the gap between two adjacent sub-pixels. Thus, a mask for manufacturing the fourth sub-pixel 204a can also be used to manufacture the sub-pixels in the first sub-pixel group 201, the second sub-pixel group 202, and the third sub-pixel group 203, so as to reduce the cost. In this case, the second sub-pixels 202a and 202b share one evaporation aperture.

The pixel structure of this exemplary embodiment is arranged in arrays with the “pixel group 20” as a unit, and the four sub-pixel groups in each pixel group are arranged in an array of two rows and two columns, thereby enabling to realize an uniform spatial distribution of pixels and a good display effect. The pixel structure of this exemplary embodiment is changed greatly compared to the pixel structure shown in FIG. 1. Therefore, division (or in other words, a display driving manner) of the pixel units for the pixel structure of this exemplary embodiment is also changed, and each divided pixel unit includes sub-pixels of four colors, enabling to achieve a more excellent display effect. Specifically, referring to FIG. 2A, each sub-pixel 204a may be shared by the two sub-pixels 202a and 202b above the sub-pixel 204a, to form two pixel units Pixel 1 and Pixel 2. Each of the pixel units Pixel 1 and Pixel 2 includes one first sub-pixel, one second sub-pixel, one third sub-pixel, and the shared fourth sub-pixel. As such, the pixel units in the pixel space formed in this manner are uniformly arranged in the row and column direction, greatly enhancing display uniformity. Moreover, when the four colors are R, G, B, and the fourth color, each pixel unit comprises the colors of R, G, B, and the fourth color, and the addition of the fourth color changes the color gamut from an original triangular shape to a quadrangular shape, widening the color gamut and reducing the power consumption. In addition, when the fourth color is cyan, the color reproduction capacity is able to be improved. When the color of the fourth sub-pixel group 204 is blue, the fourth sub-pixel 204a in the fourth sub-pixel group 204 is elongated in size with respect to other sub-pixels, enabling to enhance the display effect of blue and green colors and more effectively reproduce colors of nature, such as ocean, sky, and summer.

It should be noted that, the shapes and sizes of the sub-pixels of different colors can be adaptively adjusted according to the service life of each sub-pixel. The shapes of sub-pixels of each color may be strips, and the strip may be a right-angled rectangle, a round rectangle, and a notched rectangle (at least one angle of the rectangle is neither a right angle nor a rounded angle). A length-width ratio of the rectangle corresponding to the strip may be 1:1, 2:1. 3:1, 3:2, or 4:3, to optimize the wiring space. Preferably, in a same pixel group, all sub-pixels belonging to the second-type sub-pixel group are identical in shape and size, so that the same mask is able to be used to evaporate sub-pixels of different colors belonging to the second-type sub-pixel group in an offset manner, thereby saving the costs. For example, in FIG. 2A, in each pixel group 20, the first sub-pixels 201a and 201b, the second sub-pixels 202a and 202b, and the third sub-pixels 203a and 203b, which belong to the second-type sub-pixel groups, are all identical in shape and size. Thus, a same mask can be used to perform evaporation for three times to form the first sub-pixels, the second sub-pixels, and the third sub-pixels respectively, to reduce the process costs. More preferably, each of the sub-pixels in each pixel group 20 has a shape of a rectangle. The two side-by-side sub-pixels in each of the first sub-pixel group 201, the second sub-pixel group 202, and the third sub-pixel group 203 share one evaporation aperture. The width of the fourth sub-pixel 204a is the same as that of the first sub-pixel 210a. The left edge of the fourth sub-pixel 204a aligns with the left edge of the second sub-pixel 202a, and the right edge of the fourth sub-pixel 204a aligns with the right edge of the second sub-pixel 202b. That is, each of the sub-pixels in each pixel group has a shape of a rectangle. In addition, the width of the rectangle corresponding to a sub-pixel (i.e., the fourth sub-pixel 204a) in the first-type sub-pixel group is equal to the width of the rectangle corresponding to a sub-pixel (i.e., the second sub-pixel 202a or 202b) in the second-type sub-pixel group; and the length of the rectangle corresponding to the sub-pixel (i.e., the fourth sub-pixel 204a) in the first-type sub-pixel group is equal to the sum of the lengths of two side-by-side sub-pixels (i.e., the second sub-pixels 202a and 202b) in the second-type sub-pixel group (i.e., the second sub-pixel group 202) and the length of the gap between the two side-by-side sub-pixels. As such, a same mask is able to be used to perform evaporation for four times to form sub-pixels of four colors respectively, thus further reducing the process costs.

Moreover, it can be understood that, in practical production, a certain deviation is allowed between the actual shapes (and sizes) of various products and the designed shapes (and sizes) of various products. In general, as long as the actual shape (and size) of the product is within the allowable deviation range of the designed shape (and size) of the product, the requirements of use can be met. For example, the shapes of the sub-pixels of a certain color may also be rectangle-like shapes, such as an approximately rectangular or approximately square trapezoid. The trapezoid may be an isosceles trapezoid or a non-isosceles trapezoid, and may be a regular trapezoid, an inverted trapezoid, a trapezoid rotating 90 degrees to the left or a trapezoid rotating 90 degrees to the right. In a preferred solution, the trapezoid is an isosceles trapezoid, the difference in size between the upper base and the lower base of the isosceles trapezoid being less than 10% of the length of the lower base, an included angle of the waist and the upper side of the isosceles trapezoid being greater than 90 degrees and less than 100 degrees, an included angle of the waist and the lower base of the isosceles trapezoid being greater than 80 degrees and less than 90 degrees. In this way, the shapes of the sub-pixels of a certain color are approximately square (within the allowable deviation range), and thus a better arrangement effect can stilled be obtained.

Further, according to needs of actual design and production, the pixel structure shown in FIG. 2A may be rotated by 90 degrees to the left or right, and certainly, may also be rotated by 180 degrees. For example, a pixel structure as shown in FIG. 2B can be obtained by rotating FIG. 2A by 90 degrees to the left. Differences between the pixel structure shown in FIG. 2B and that shown in FIG. 2A are as follows: the two sub-pixels in each of the second-type sub-pixel groups (i.e., the first sub-pixel group 201, the second sub-pixel group 202, and the third sub-pixel group 203) are changed from a horizontal side-by-side layout (that is, being arranged in a row to present a form of two columns and one row) to a vertical side-by-side layout (that is, being arranged in a column to present a form of two rows and one column) A direction of elongation of the sub-pixels (i.e., the fourth sub-pixel 204a) in the first-type sub-pixel group (i.e., the fourth sub-pixel group 204) is changed from a horizontal direction to a vertical direction. That is, the two sub-pixels in each second-type sub-pixel group are arranged along the length direction of the sub-pixels in the first-type sub-pixel group. In addition, in FIG. 2B, the fourth sub-pixel group 204 is located at the left side of the second sub-pixel group 202, and the fourth sub-pixel 204a is shared by the two second sub-pixels 202a and 202b at the right side.

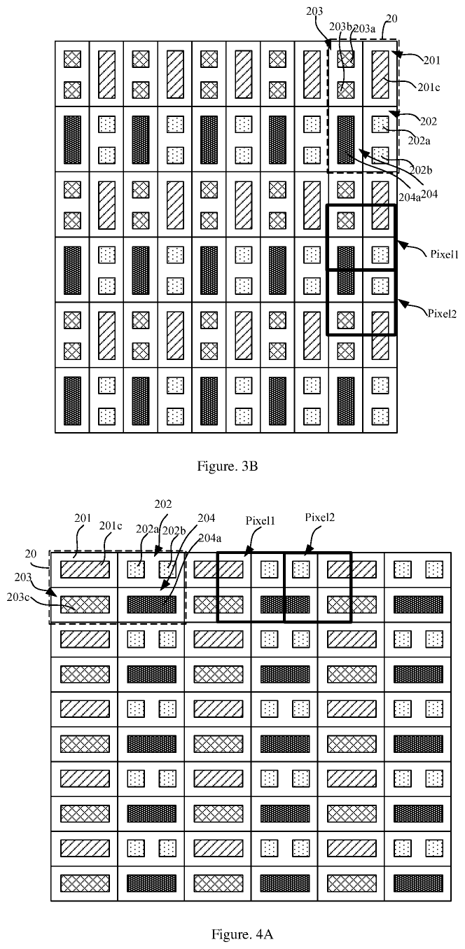

Referring to FIG. 3A, a first sub-pixel 201c second sub-pixels 202a and 202b are successively arranged in a row, and third sub-pixels 203a and 203b and a fourth sub-pixel 204a are successively arranged in a row. The first sub-pixel 201c is shared by each of the two third sub-pixels 203a and 203b below the first sub-pixel (or in other words, the first sub-pixel 201c is shared by one adjacent second sub-pixel at the left side thereof and one adjacent second sub-pixel at right side thereof), and the fourth sub-pixel 204a is shared by the two second sub-pixels 202a and 202b above the fourth sub-pixel 204a (or in other words, the fourth sub-pixel 204c is shared by one adjacent third sub-pixel at the left side thereof and one adjacent third sub-pixel at the right side thereof). The width of the rectangle corresponding to a sub-pixel in the first-type sub-pixel group is equal to the width of the rectangle corresponding to a sub-pixel in the second-type sub-pixel group; and the length of the rectangle corresponding to a sub-pixel in the first-type sub-pixel group is equal to a sum of lengths of two adjacent sub-pixels in the second-type sub-pixel group and the length of a gap between the two adjacent sub-pixels. Thus, a mask for manufacturing the fourth sub-pixel 204a is also able to be used to manufacture sub-pixels in a first sub-pixel group 201, a second sub-pixel group 202, and a third sub-pixel group 203, so as to reduce the costs. In this case, the second sub-pixels 202a and 202b share one evaporation aperture.

The difference between the pixel structure shown in FIG. 3A and FIG. 2A is as follow: the number of the first-type sub-pixel groups is changed from one to two. Thus, each of the two formed pixel units Pixel 1 and Pixel 2 includes the shared first sub-pixel, one second sub-pixel, one third sub-pixel, and the shared fourth sub-pixel. Such a pixel structure enhances the spatial utilization of both the first sub-pixel and the fourth sub-pixel, further increasing the pixel aperture ratio and thus further enhancing the PPI. For the pixel structure shown in FIG. 3A, the arrangements of specific sub-pixel groups and sub-pixels therein may refer to the arrangements of the first-type sub-pixel groups and the second-type sub-pixel groups and sub-pixels therein in FIG. 2A, and the details are not described herein again. It should be noted that, in the pixel structure shown in FIG. 3A, the two first-type sub-pixel groups are diagonally disposed in an array formed by the four sub-pixel groups. In other exemplary embodiments, the two first-type sub-pixel groups may also be arranged next to each other horizontally (in a row) or vertically (in a column).

Each of sub-pixels in each pixel group 20 has a shape of a rectangle. The two side-by-side sub-pixels in each of the second sub-pixel group 202 and the third sub-pixel group 203 share one evaporation aperture. Each of the first sub-pixel 201c and the fourth sub-pixel 204a is identical with the second sub-pixel 202a in width. The left edge of the fourth sub-pixel 204a aligns with the left edge of the second sub-pixel 202a, the right edge of the fourth sub-pixel 204a aligns with the right edge of the second sub-pixel 202b. The left edge of the first sub-pixel 201c aligns with the left edge of the third sub-pixel 203a, and the right edge of the first sub-pixel 201c aligns with the right edge of the third sub-pixel 203b. That is, each of sub-pixels in each pixel group has a shape of a rectangle. In addition, the width of the rectangle corresponding to a sub-pixel (i.e., the first sub-pixel 201c or the fourth sub-pixel 204a) in the first-type sub-pixel group is equal to the width of the rectangle corresponding to a sub-pixel (i.e., the second sub-pixel 202a) in the second-type sub-pixel group. And the length of the rectangle corresponding to the sub-pixel (i.e., the first sub-pixel 201c or the fourth sub-pixel 204a) in the first-type sub-pixel group is equal to the sum of the lengths of two side-by-side sub-pixels (i.e., the second sub-pixels 202a and 202b) in the second-type sub-pixel group (i.e., the second sub-pixel group 202) and the length of the gap between the two side-by-side sub-pixels. As such, a same mask is able to be used to perform evaporation for four times to form sub-pixels of four colors respectively, further reducing the process costs.

Further, according to needs of actual design and production, the pixel structure shown in FIG. 3A may be rotated by 90 degrees to the left or right, and certainly, may also be rotated by 180 degrees. For example, a pixel structure as shown in FIG. 3B can be obtained by rotating FIG. 3A by 90 degrees to the left. Differences between the pixel structure shown in FIG. 3B and FIG. 3A are as follows: the two sub-pixels in each of the second-type sub-pixel groups (i.e., the second sub-pixel group 202 and the third sub-pixel group 203) are changed from a horizontal side-by-side layout (that is, being arranged in a row) to a vertical side-by-side layout (that is, being arranged in a column). A direction of elongation of each of the sub-pixels in the first-type sub-pixel groups (i.e., the first sub-pixel group 201 and the fourth sub-pixel group 204) is changed from a horizontal direction to a vertical direction. The first sub-pixel group 201 is located at the right side of the third sub-pixel group 203, and the first sub-pixel 201c is shared by the two third sub-pixels 203a and 203b at the left side thereof. The fourth sub-pixel group is located at the left side of the second sub-pixel group 202, and the fourth sub-pixel 204a is shared by the two second sub-pixels 202a and 202b at the right side thereof.

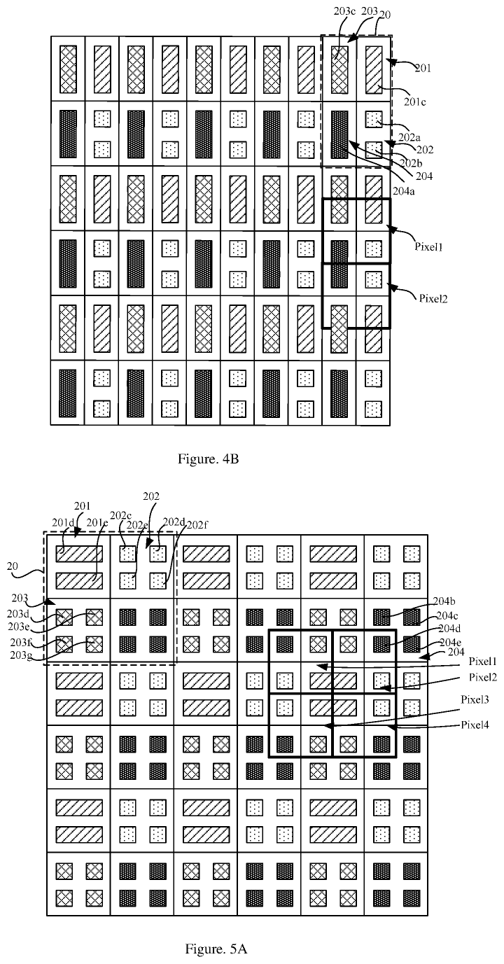

Referring to FIG. 4A, the first sub-pixel 201c and second sub-pixels 202a and 202b are successively arranged in a row, and the third sub-pixel 203c and the fourth sub-pixel 204a are successively arranged in a row. The first sub-pixel 201c and the third first sub-pixel 203c are shared by one adjacent second sub-pixel at the left side thereof and one adjacent second sub-pixel at the right side thereof, and the fourth sub-pixel 204a is shared by each of the two second sub-pixels 202a and 202b above the fourth sub-pixel 204a.

The width of a rectangle corresponding to a sub-pixel in a first-type sub-pixel group is equal to the width of a rectangle corresponding to a sub-pixel in a second-type sub-pixel group; and the length of a rectangle corresponding to a sub-pixel in the first-type sub-pixel group is equal to the sum of lengths of two adjacent sub-pixels in the second-type sub-pixel group and the length of a gap between the two adjacent sub-pixels. Thus, a mask for manufacturing the fourth sub-pixel 204a is also able to be used to manufacture sub-pixels in a first sub-pixel group 201, a second sub-pixel group 202, and a third sub-pixel group 203, so as to reduce the costs. In this case, the second sub-pixels 202a and 202b share one evaporation aperture.

The difference between the pixel structure shown in FIG. 4A and FIG. 2A is as follow: the number of the first-type sub-pixel groups is changed from one to three. Thus, each of the two formed pixel units Pixel 1 and Pixel 2 includes the shared first sub-pixel, one second sub-pixel, the shared third sub-pixel, and the shared fourth sub-pixel. Such a pixel structure enhances the spatial utilization of each of the first sub-pixel, the third sub-pixel and the fourth sub-pixel, further increasing the pixel aperture ratio and thus further enhancing the PPI. For the pixel structure shown in FIG. 4A, the arrangements of specific sub-pixel groups and sub-pixels therein may refer to the arrangements of the first-type sub-pixel groups and the second-type sub-pixel groups and sub-pixels therein in FIG. 2A, and details are not described herein again.

Each of sub-pixels in each pixel group 20 has a shape of a rectangle. The first sub-pixel 201c, the third first sub-pixel 203c, and the fourth sub-pixel 204a are all identical in shape and size. The two side-by-side sub-pixels in the second sub-pixel group 202 share one evaporation aperture. Each of the first sub-pixel 201c, the third first sub-pixel 203c, and the fourth sub-pixel 204a is identical with the second sub-pixel 202a in width. The left edge of the fourth sub-pixel 204a aligns with the left edge of the second sub-pixel 202a, and the right edge of the fourth sub-pixel 204a aligns with the right edge of the second sub-pixel 202b. That is, each sub-pixel in each pixel group has a shape of a rectangle. In addition, the width of a rectangle corresponding to a sub-pixel (i.e., the first sub-pixel 201c, the third sub-pixel 203c, or the fourth sub-pixel 204a) in the first-type sub-pixel group is equal to the width of a rectangle corresponding to a sub-pixel (i.e., the second sub-pixel 202a) in the second-type sub-pixel group. And the length of a rectangle corresponding to a sub-pixel (i.e., the first sub-pixel 201c or the fourth sub-pixel 204a) in the first-type sub-pixel group is equal to the sum of the lengths of two side-by-side sub-pixels (i.e., the second sub-pixels 202a and 202b) in the second-type sub-pixel group (i.e., the second sub-pixel group 202) and the length of the gap between the two side-by-side sub-pixels. As such, a same mask is able to be used to perform evaporation for four times to form sub-pixels of four colors separately, further reducing the process costs.

Further, according to needs of actual design and production, the pixel structure shown in FIG. 4A may be rotated by 90 degrees to the left or right, and certainly, may also be rotated by 180 degrees. For example, a pixel structure as shown in FIG. 4B can be obtained by rotating FIG. 4A by 90 degrees to the right. Differences between the pixel structure shown in FIG. 4B and FIG. 4A are as follow: the two sub-pixels (i.e., the second sub-pixels 202a and 202b) in the second-type sub-pixel group (i.e., the second sub-pixel group 202) are changed from a horizontal side-by-side layout (that is, being arranged in a row) to a vertical side-by-side layout (that is, being arranged in a column). A direction of elongation of the sub-pixels in each of the first-type sub-pixel groups (i.e., the first sub-pixel group 201, the third sub-pixel group 203, and the fourth sub-pixel group 204) is changed from a horizontal direction to a vertical direction. The first sub-pixel group 201 is located at the right side of the third sub-pixel group 203, and the first sub-pixel 201c is shared by one adjacent second sub-pixel above the first sub-pixel 201c and one adjacent second sub-pixel below the first sub-pixel 201c. The fourth sub-pixel group is located at the left side of the second sub-pixel group 202, and the fourth sub-pixel 204a is shared by each of the two second sub-pixels 202a and 202b at the right side.

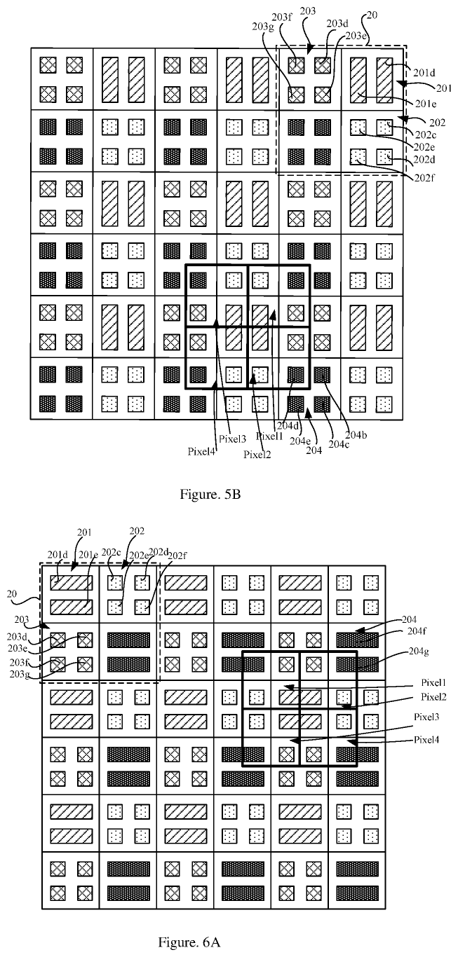

Referring to FIG. 5A, two first sub-pixels 201d and 201e in a first sub-pixel group 201 are arranged in two rows and one column, which are respectively aligned with the two rows formed by second sub-pixels 202c, 202d, 202e and 202f in a second sub-pixel group 202. That is, the first sub-pixel 201d and the second sub-pixels 202c and 202d are successively arranged in a row, and the first sub-pixel 201e and the second sub-pixels 202e and 202f are successively arranged in a row. Third sub-pixels 203d and 203e in a third sub-pixel group 203 and fourth sub-pixels 204b and 204c in a fourth sub-pixel group 204 are successively arranged in a row; and third sub-pixels 203f and 203g in the third sub-pixel group 203 and fourth sub-pixels 204d and 204e in the fourth sub-pixel group 204 are successively arranged in a row. The first sub-pixel 201e is shared by each of the two adjacent third sub-pixels 203d and 203e below the first sub-pixel 201e, and the first sub-pixel 201d is shared by each of the two adjacent third sub-pixels (not shown) above the first sub-pixel 201d. The width of a rectangle corresponding to a sub-pixel in a first-type sub-pixel group is equal to the width of a rectangle corresponding to a sub-pixel in a second-type sub-pixel group; and the length of a rectangle corresponding to a sub-pixel in a first-type sub-pixel group is equal to the sum of lengths of two adjacent sub-pixels in the second-type sub-pixel group and the length of a gap between the two adjacent sub-pixels. Thus, a mask for manufacturing the first sub-pixel 201d or both the first sub-pixels 201d and 201e (in this case, the first sub-pixels 201d and 201e share one evaporation aperture) is also able to be used to manufacture the sub-pixels in the second sub-pixel group 202, the third sub-pixel group 203, and the fourth sub-pixel group 204, so as to reduce the costs. In this case, the second sub-pixels 202a and 202b share one evaporation aperture.

The differences between the pixel structure shown in FIG. 5A and FIG. 2A are as follow: the number of sub-pixels in the first-type sub-pixel group is changed from one to two, and the number of sub-pixels in each second-type sub-pixel group is changed from two to four. Each sub-pixel in the first-type sub-pixel group is shared by two adjacent third sub-pixels in the same column (or in other words, it is shared by one adjacent second sub-pixel at the left side thereof and one adjacent second sub-pixel at right side thereof), to form four pixel units Pixel 1, Pixel 2, Pixel 3, and Pixel 4. Each pixel unit includes the shared first sub-pixel, one second sub-pixel, one third sub-pixel, and one fourth sub-pixel. Such a pixel structure doubles the pixel unit in number, and enhances the PPI and resolution. For the pixel structure shown in FIG. 5A, the arrangement of sub-pixels of a same color in a same row may refer to the arrangements of sub-pixels in a same row in the pixel structure shown in FIG. 2A, and the details are not described herein again. In addition, it should be noted that, according to needs of actual design and production, for the first-type sub-pixel group, the first sub-pixel group 201 may be replaced with the third sub-pixel group 203 or the fourth sub-pixel group 204.

It should be noted that, in the pixel structure shown in FIG. 5A, the shapes and sizes of the sub-pixels of different colors may be adaptively adjusted according to the service life of each sub-pixel. For example, the shapes of the first sub-pixel 201d and the second sub-pixel 202c are both strips, and the sizes of the first sub-pixel 201d may be less than, equal to, or greater than that of the second sub-pixel 202c. Specifically, for example, the width of the first sub-pixel 201d is less than, equal to, or greater than that of the second sub-pixel 202c; and the length of the first sub-pixel 201d is equal to, greater than, or less than the length of a region defined by the side-by-side arranged third sub-pixels 203d and 203e. The sub-pixel of each color may be strip-shaped. The strip may be a right-angled rectangle, a round rectangle, and a notched rectangle (at least one angle of the rectangle is neither a right angle nor a rounded angle). A length-width ratio of the rectangle corresponding to the strip shape may be 1:1, 2:1, 3:1, 3:2 or 4:3, to optimize wiring space. Preferably, in a same pixel group, each of the sub-pixels of a same color is identical in shape and size, and each sub-pixel in the second-type sub-pixel groups is identical in shape and size, so that the same mask is able to be used to make sub-pixels of three different colors in the second-type sub-pixel groups, thereby saving the costs. For example, in FIG. 5A, in each pixel group 20, all sub-pixels in the second sub-pixel group 202, the third sub-pixel group 203, and the fourth sub-pixel group 204 each belonging to the second-type sub-pixel group are identical in shape and size. Therefore, a same mask is able to be used to perform evaporation for three times to form each of the second sub-pixels, the third sub-pixels, and the fourth sub-pixels, so as to reduce the process costs. More preferably, each sub-pixel in each pixel group 20 has a shape of a rectangle. All sub-pixels in the second sub-pixel group 202, the third sub-pixel group 203, and the fourth sub-pixel group 204 each belonging to the second-type sub-pixel group are identical in shape and size. The two sub-pixels or the four sub-pixels in each sub-pixel group share one evaporation aperture. The first sub-pixels 201d and 201e are identical with the second sub-pixel 202a in width. The left edges of the first sub-pixels 201d and 201e align with the left edge of the third sub-pixel 203d; and the right edges of the first sub-pixels 201d and 201e align with the right edge of the third sub-pixel 203e. That is, each sub-pixel in each pixel group has a shape of a rectangle. In addition, the width of a rectangle corresponding to a sub-pixel (i.e., the first sub-pixel 201d or 201e) in the first-type sub-pixel group is equal to the width of a rectangle corresponding to a sub-pixel (i.e., the second sub-pixel 202c) in the second-type sub-pixel group. And the length of a rectangle corresponding to the sub-pixel (i.e., the first sub-pixel 201d or 201e) in the first-type sub-pixel group is equal to the sum of the lengths of two side-by-side sub-pixels (i.e., the second sub-pixels 202c and 202d) in the second-type sub-pixel group (i.e., the second sub-pixel group 202) and the length of the gap between the two side-by-side sub-pixels. In this case, the formed four pixel units Pixel 1, Pixel 2, Pixel 3, and Pixel 4 that are next to each other are all squares. A first sub-pixel, a second sub-pixel, a third sub-pixel and a fourth sub-pixel are respectively located at the four vertexes of each square. The side length of the square is equal to a pitch between the pixel units. Thus, a same mask is able to be used to perform evaporation in an offset manner to form sub-pixels of four different colors respectively, thus further reducing the process costs.

Further, according to needs of actual design and production, the pixel structure shown in FIG. 5A may be rotated by 90 degrees to the left or right, and certainly, may also be rotated by 180 degrees. For example, a pixel structure as shown in FIG. 5B can be obtained by rotating FIG. 5A by 90 degrees to the right. Differences between the pixel structure shown in FIG. 5B and FIG. 5A are as follow: the two sub-pixels (i.e., the first sub-pixels 202d and 202e) in the first-type sub-pixel group (i.e., the first sub-pixel group 201) are changed from a vertical side-by-side layout (that is, being arranged in a column) into a horizontal side-by-side layout (that is, being arranged in a row). A direction of elongation of the two sub-pixels is changed from a horizontal direction into a vertical direction. The first sub-pixel group 201 is located at the right side of the third sub-pixel group 203, each first sub-pixel is shared by one adjacent second sub-pixel of the same column over the first sub-pixel and one adjacent second sub-pixel of the same column below the first sub-pixel, and the fourth sub-pixel group 204 is located at the left side of the second sub-pixel group 202.

Referring to FIG. 6A, two first sub-pixels 201d and 201e in a first sub-pixel group 201 are arranged in two rows and one column, which are respectively aligned with the two rows formed by second sub-pixels 202c, 202d,202e and 202f in a second sub-pixel group 202. That is, the first sub-pixel 201d and the second sub-pixels 202c and 202d are successively arranged in a row, and the first sub-pixel 201e and the second sub-pixels 202e and 202f are successively arranged in a row. Two fourth sub-pixels 204f and 204g in a fourth sub-pixel group 204 are arranged in two rows and one column, which are respectively aligned with the two rows formed by third sub-pixels 203d, 203e, 203f and 203g in a third sub-pixel group 203. That is, the fourth sub-pixel 204f and the third sub-pixels 203d and 203e are successively arranged in a row, and the fourth sub-pixel 204g and the third sub-pixels 203f and 203g are successively arranged in a row. Each of first sub-pixels 201d and 201e is shared by one adjacent second sub-pixel of the same row at the left side thereof and one adjacent second sub-pixel of the same row at right side thereof. And each of the fourth sub-pixels 204f and 204g is shared by one adjacent third sub-pixel of the same row at the left side thereof and one adjacent third sub-pixel of the same row at right side thereof.

The difference between the pixel structure shown in FIG. 6A and FIG. 5A is as follow: the number of the first-type sub-pixel groups is changed from one to two. Thus, four formed pixel units Pixel 1, Pixel 2, Pixel 3, and Pixel 4 each includes the shared first sub-pixel, one second sub-pixel, one third sub-pixel, and the shared fourth sub-pixel. Such a pixel structure enhances the spatial utilization of both the first sub-pixel and the fourth sub-pixel, further increasing the pixel aperture ratio, and further enhancing the PPI. For the pixel structure shown in FIG. 6A, the arrangement of specific sub-pixel groups and sub-pixels therein may refer to the arrangement of the first-type sub-pixel groups and the second-type sub-pixel groups and the sub-pixels therein in FIG. 5A and FIG. 3A, and the details are not described herein again. It should be noted that, in the pixel structure shown in FIG. 6A, the two first-type sub-pixel groups are diagonally disposed in an array formed by the four sub-pixel groups. In other exemplary embodiments, the two first-type sub-pixel groups may also be arranged next to each other horizontally (in a row) or vertically (in a column).

It should be noted that, in the pixel structure shown in FIG. 6A, the shapes and sizes of the sub-pixels of different colors may be adaptively adjusted according to the service life of each sub-pixel. For example, the sub-pixels in the first sub-pixel group 201 and the sub-pixels in the fourth sub-pixel group 204 are identical in shape but different in size (for example, the widths of the first sub-pixel 201d and the fourth sub-pixel 204f are identical, and may be both less than the width of the second sub-pixel 202c. The length of the first sub-pixel 201d is equal to or greater than the length of a region defined by the side-by-side third sub-pixels 203d and 203e. And the length of the fourth sub-pixel 204f is less than the length of a region defined by the side-by-side arranged third sub-pixels 203d and 203e). Preferably, in the same pixel group, the sub-pixels of the same color are identical in shape and size. All sub-pixels in the first-type sub-pixel group are identical in shape and size, and all sub-pixels in the second-type sub-pixel group are identical in shape and size. Thus, a same mask is able to be used to make the sub-pixels of different colors in the first-type sub-pixel group in an offset manner, and another mask is able to be used to make the sub-pixels of different colors in the second-type sub-pixel group in an offset manner. For example, in FIG. 6A, in each pixel group 20, all sub-pixels in the second sub-pixel group 202 and the third sub-pixel group 203 each belonging to the second type are identical in shape and size. Therefore, a same mask is able to be used to perform evaporation for twice to form the second sub-pixels and the third sub-pixels respectively, to reduce the process costs. Similarly, all sub-pixels in the first sub-pixel group 201 and the fourth sub-pixel group 204 each belonging to the first type are identical in shape and size. Therefore, a same mask is able to be used to perform evaporation for twice to form the first sub-pixels and the fourth sub-pixels respectively, to further reduce the process costs. More preferably, each sub-pixel in each pixel group 20 has a shape of a rectangle. All sub-pixels in the second sub-pixel group 202 and the third sub-pixel group 203 each belonging to the second type are identical in shape and size. The two side-by-side sub-pixels or the four sub-pixels in the second sub-pixel group 202 or the third sub-pixel group 203 share one evaporation aperture. All sub-pixels in the first sub-pixel group 201 and the fourth sub-pixel group 204 each belonging to the first type are identical in shape and size. Each first sub-pixel and each fourth sub-pixel are identical with each second sub-pixel 202a in width. The left edges of the first sub-pixels 201d and 201e align with the left edge of the third sub-pixel 203d; the right edges of the first sub-pixels 201d and 201e align with the right edge of the third sub-pixel 203e; the left edges of the fourth sub-pixels 204f and 204g align with the left edge of the second sub-pixel 202c; and right edges of the fourth sub-pixels 204f and 204g align with the right edge of the second sub-pixel 202d. That is, each sub-pixel in each pixel group has a shape of a rectangle. In addition, the width of a rectangle corresponding to a sub-pixel (i.e., the first sub-pixel 201d or 201e, or the fourth sub-pixel 204f or 204g) in the first-type sub-pixel group is equal to the width of a rectangle corresponding to a sub-pixel (i.e., the second sub-pixel 202c) in the second-type sub-pixel group; and the length of a rectangle corresponding to the sub-pixel (i.e., the first sub-pixel 201d or 201e, or the fourth sub-pixel 204f or 204g) in the first-type sub-pixel group is equal to the sum of the lengths of two side-by-side sub-pixels (i.e., the second sub-pixels 202c and 202d) in the second-type sub-pixel group (i.e., the second sub-pixel group 202) and the length of the gap between the two side-by-side sub-pixels. In this case, the formed four pixel units Pixel 1, Pixel 2, Pixel 3, and Pixel 4 that are next to each other are all squares. A first sub-pixel, a second sub-pixel, a third sub-pixel and a fourth sub-pixel are respectively located at the four vertexes of each square. The side length of the square is equal to a pitch between the pixel units. Thus, a same mask is able to be used to perform evaporation in an offset manner to form the sub-pixels of four different colors respectively, thus further reducing the process costs.

Further, according to needs of actual design and production, the pixel structure shown in FIG. 6A may be rotated by 90 degrees to the left or right, and certainly, may also be rotated by 180 degrees. For example, a pixel structure as shown in FIG. 6B can be obtained by rotating FIG. 6A by 90 degrees to the right. Differences between the pixel structure shown in FIG. 6B and FIG. 6A are as follows: the two sub-pixels in each first-type sub-pixel group (i.e., the first sub-pixel group 201 or the fourth sub-pixel group 204) are changed from a vertical side-by-side layout (that is, being arranged in a column) into a horizontal side-by-side layout (that is, being arranged in a row). A direction of elongation of the two sub-pixels is changed from a horizontal direction into a vertical direction. The first sub-pixel group 201 is located at the right side of the third sub-pixel group 203, and each first sub-pixel is shared by one adjacent second sub-pixel of the same column over the first sub-pixel and one adjacent second sub-pixel of the same column below the first sub-pixel. The fourth sub-pixel group 204 is located at the left side of the second sub-pixel group 202, and each fourth sub-pixel is shared by two second sub-pixels of the same row closest thereto.

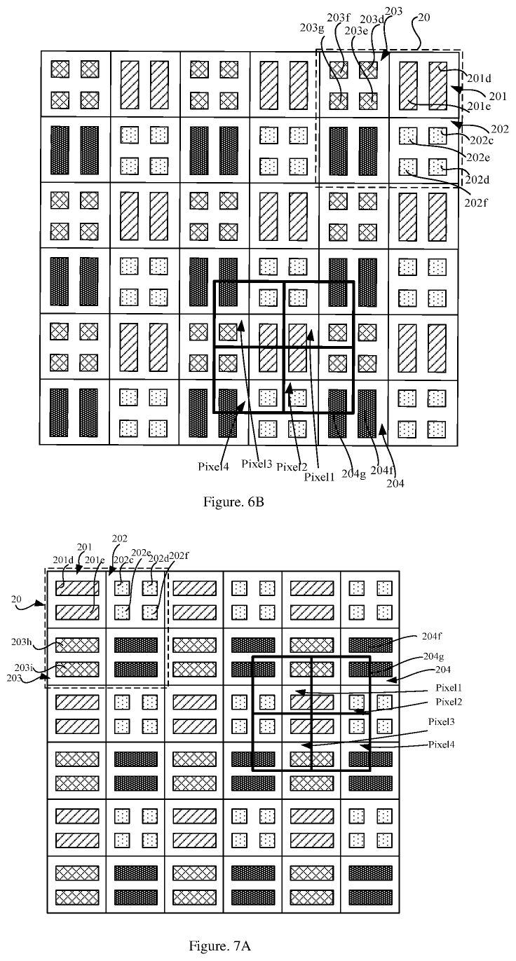

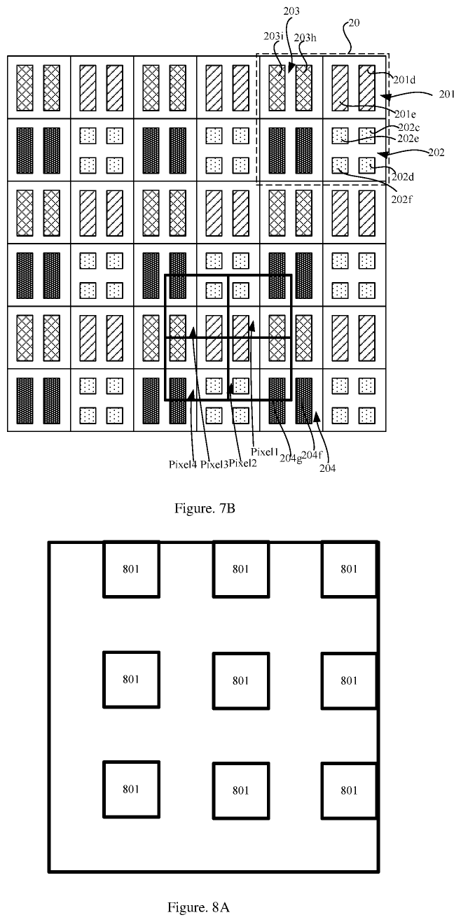

Referring to FIG. 7A, two first sub-pixels 201d and 201e in a first sub-pixel group 201 are arranged in two rows and one column, which are respectively aligned with the two rows formed by second sub-pixels 202c, 202d, 202e and 202f in a second sub-pixel group 202. That is, the first sub-pixel 201d and the second sub-pixels 202c and 202d are successively arranged in a row, and the first sub-pixel 201e and the second sub-pixels 202e and 202f are successively arranged in a row. Two third sub-pixels 203h and 203i in a third sub-pixel group 203 are arranged in two rows and one column. Two fourth sub-pixels 204f and 204g in a fourth sub-pixel group 204 are arranged in two rows and one column, which are respectively aligned with the two rows formed by the two third sub-pixels 203h and 203i in the third sub-pixel group 203. That is, the fourth sub-pixel 204f and the third sub-pixel 203h are successively arranged in a row, and the fourth sub-pixel 204g and the third sub-pixel 203i are successively arranged in a row. Each of the first sub-pixels 201d and 201e is shared by one adjacent second sub-pixel of the same row at the left side thereof and one adjacent second sub-pixel of the same row at the right side thereof; each of the fourth sub-pixels 204f and 204g is shared by two adjacent second sub-pixels of the same column; and each of the third sub-pixels 203h and 203i is shared by one adjacent fourth sub-pixel of the same row at the left side thereof and one adjacent fourth sub-pixel of the same row at the right side thereof. The width of a rectangle corresponding to a sub-pixel in a first-type sub-pixel group is equal to the width of a rectangle corresponding to a sub-pixel in a second-type sub-pixel group; and the length of a rectangle corresponding to the sub-pixel in a first-type sub-pixel group is equal to the sum of lengths of two adjacent sub-pixels in the second-type sub-pixel group and the length of a gap between the two adjacent sub-pixels. Thus, a mask for making the first sub-pixel 201d or both the first sub-pixels 201d and 201e (in this case, the first sub-pixels 201d and 201e share an evaporation aperture) is also able to be used to make sub-pixels in the second sub-pixel group 202, the third sub-pixel group 203, and the fourth sub-pixel group 204, so as to reduce the costs. In this case, at least two adjacent sub-pixels in the second sub-pixel group 202 share one evaporation aperture.

The difference between the pixel structure shown in FIG. 7A and FIG. 5A is as follows: the number of the first-type sub-pixel groups is changed from one to three. Thus, four formed pixel units Pixel 1, Pixel 2, Pixel3 and Pixel4 each includes the shared first sub-pixel, one second sub-pixel, the shared third sub-pixel, and the shared fourth sub-pixel. Such a pixel structure enhances the spatial utilization of each of the first sub-pixel, the third sub-pixel and the fourth sub-pixel, thereby further increasing the pixel aperture ratio, and thus further enhancing the PPI. For the pixel structure shown in FIG. 7A, the arrangement of specific sub-pixel groups and sub-pixels therein may refer to the arrangement of the first-type sub-pixel group and the second-type sub-pixel group and the sub-pixels therein in FIG. 5A and FIG. 4A, and the details are not described herein again.

It should be noted that, in the pixel structure shown in FIG. 7A, the shapes and sizes of the sub-pixels of different colors may be adaptively adjusted according to the service life of each sub-pixel. For example, the sub-pixels in the first sub-pixel group 201, the third sub-pixel group 203 and the fourth sub-pixel group 204 are all identical in shape, but are not all identical in size (for example, the widths of the first sub-pixel 201d, the third sub-pixel 203h and the fourth sub-pixel 204f are identical, and may be all less than or equal to the width of the second sub-pixel 202c; the length of the first sub-pixel 201d is equal to or greater than that of the third sub-pixel 203h; the length of the fourth sub-pixel 204f is less than that of the third sub-pixel 203h; and the length of the third sub-pixel 203h may be equal to, less than or greater than the length of a region defined by the side-by-side arranged second sub-pixels 202c and 202d). Preferably, in the same pixel group, the sub-pixels of a same color are identical in shape and size, and all sub-pixels in the first-type sub-pixel groups are identical in shape and size. Thus, a same mask is able to be used to make the sub-pixels of different colors in the first-type sub-pixel groups in an offset manner. For example, in FIG. 7A, in each pixel group 20, all sub-pixels in the first sub-pixel group 201, the third sub-pixel group 203, and the fourth sub-pixel group 204 each belonging to the first type are identical in shape and size. Therefore, a same mask is able to be used to perform a corresponding offset and evaporation to form each of the second sub-pixels, the third sub-pixels and the fourth sub-pixels, so as to reduce the process costs. More preferably, each sub-pixel in each pixel group 20 has a shape of a rectangle. All sub-pixels in the second sub-pixel group 202 belonging to the second type are identical in shape and size. Two side-by-side sub-pixels or the four sub-pixels in the second sub-pixel group 202 share one evaporation aperture. All sub-pixels in the first sub-pixel group 201, the third sub-pixel group 203, and the fourth sub-pixel group 204 each belonging to the first type are identical in shape and size. The first sub-pixels, third sub-pixels, and fourth sub-pixels are all identical with the second sub-pixels 202a in width. The left edges of the fourth sub-pixels 204f and 204g align with the left edge of the second sub-pixel 202c; and the right edges of the fourth sub-pixels 204f and 204g align with the right edge of the second sub-pixel 202d. That is, each sub-pixel in each pixel group has a shape of a rectangle. In addition, the width of a rectangle corresponding to a sub-pixel (i.e., the first sub-pixel 201d or 201e, or the third sub-pixel 203h or 203i, or the fourth sub-pixel 204f or 204g) in the first-type sub-pixel group is equal to the width of a rectangle corresponding to a sub-pixel (i.e., the second sub-pixel 202c) in the second-type sub-pixel group; and the length of a rectangle corresponding to the sub-pixel (i.e., the first sub-pixel 201d or 201e, or the third sub-pixel 203h or 203i, or the fourth sub-pixel 204f or 204g) in the first-type sub-pixel group is equal to the sum of the lengths of two side-by-side sub-pixels (i.e., the second sub-pixels 202c and 202d) in the second-type sub-pixel group (i.e., the second sub-pixel group 202) and the length of the gap between the two side-by-side sub-pixels. In this case, the formed four pixel units Pixel 1, Pixel 2, Pixel 3, and Pixel 4 are all squares. A first sub-pixel, a second sub-pixel, a third sub-pixel and a fourth sub-pixel are respectively located at the four vertexes of each square. The side length of the square is equal to a pitch between the pixel units. Thus, a same mask is able to be used to perform evaporation in an offset manner to form the sub-pixels of four different colors respectively, thus further reducing the process costs.

Further, according to needs of actual design and production, the pixel structure shown in FIG. 7A may be rotated by 90 degrees to the left or right, and certainly, may also be rotated by 180 degrees. For example, a pixel structure as shown in FIG. 7B can be obtained by rotating FIG. 7A by 90 degrees to the right. Differences between the pixel structure shown in FIG. 7B and FIG. 7A are as follow: the two sub-pixels in each first-type sub-pixel group (i.e., the first sub-pixel group 201, the third sub-pixel group 203 or the fourth sub-pixel group 204) are changed from a vertical side-by-side layout (that is, being arranged in a column) to a horizontal side-by-side layout (that is, being arranged in a row). A direction of elongation of the two sub-pixels is changed from a horizontal direction to a vertical direction. The first sub-pixel group 201 is located at the right side of the third sub-pixel group 203, and each first sub-pixel is shared by one adjacent second sub-pixel of the same column over the first sub-pixel and one adjacent second sub-pixel of the same column below the first sub-pixel. The fourth sub-pixel group 204 is located at the left side of the second sub-pixel group 202, and each fourth sub-pixel is shared by two second sub-pixels of the same row closest thereto. In the pixel structure of each exemplary embodiment of the present disclosure, each sub-pixel includes a light-emitting region (a display region) and a non-light-emitting region (a non-display region). The light-emitting region of each sub-pixel includes a cathode, an anode and an electroluminescent layer (also called organic emission layer), and the electroluminescent layer is located between the cathode and the anode and configured to generate light of a predetermined color to achieve display. For the pixel structure of the present disclosure, the evaporation process needs to be performed for at least four times to produce electroluminescent layers of corresponding colors (for example, red, green, blue and a fourth color) in light-emitting regions of corresponding sub-pixels respectively. A mask related to the second sub-pixel group of the pixel structure of the present disclosure is used as an example below to describe the evaporation process for the pixel structure of the present disclosure in detail.

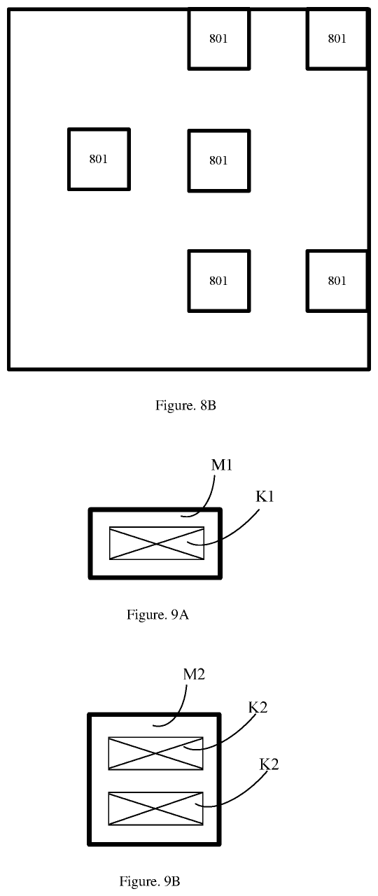

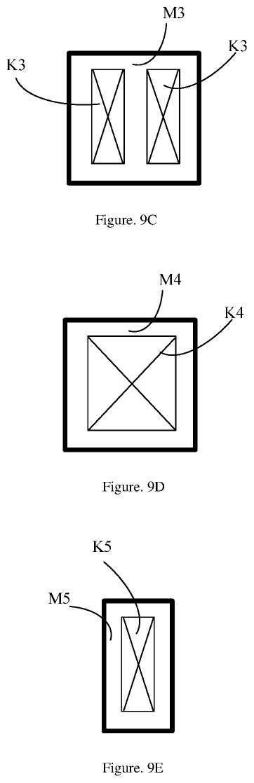

FIG. 8A is a schematic diagram of a mask (FMM) used for evaporation of second sub-pixels of all second sub-pixel groups in the pixel structure of each exemplary embodiment of the present disclosure. As shown in FIG. 8A, the mask has a plurality of evaporation apertures 801 aligned in rows and columns Each evaporation aperture 801 corresponds to the second sub-pixel group 202 at a corresponding position of FIG. 2A to FIG. 7B, and the shape and size of each evaporation aperture 801 can be designed according to an arrangement of second sub-pixels of a second sub-pixel group 202. Specifically, when making the second sub-pixel group 202 in the pixel structure shown in FIG. 2A, FIG. 3A or FIG. 4A, the mask used may be in the form of M1 shown in FIG. 9A. That is, the two sub-pixels of each second sub-pixel group 202 in the pixel structure shown in FIG. 2A, FIG. 3A or FIG. 4A share one evaporation aperture, i.e., each evaporation aperture 801 is in the form of K1. When making the second sub-pixel group 202 in the pixel structure shown in FIG. 2B, FIG. 3B or FIG. 4B, the mask for making the second sub-pixel group 202 in the pixel structure shown in FIG. 2A, FIG. 3A or FIG. 4A may be directly rotated to a corresponding direction, to present an form of M5 shown in FIG. 9E; and in this case, each evaporation aperture 801 is in the form of K5. When making the second sub-pixel group 202 in the pixel structure shown in FIG. 5A, FIG. 6A or FIG. 7A, the mask adopted may be in the form M2 shown in FIG. 9B or M3 shown in FIG. 9C, or M4 shown in FIG. 9D. When the used mask is in the form of M2 shown in FIG. 9B, the two horizontally side-by-side second sub-pixels of each second sub-pixel group 202 in the pixel structure shown in FIG. 5A, FIG. 6A or FIG. 7A share one evaporation aperture, that is, each evaporation aperture 801 is in the form of K2. When the used mask is in the form of M3 shown in FIG. 9C, the two vertically side-by-side second sub-pixels of each second sub-pixel group 202 in the pixel structure shown in FIG. 5A, FIG. 6A or FIG. 7A share one evaporation aperture, that is, each evaporation aperture 801 is in the form of K3. When the used mask is in the form of M4 shown in FIG. 9D, the four second sub-pixels of each second sub-pixel group 202 in the pixel structure shown in FIG. 5A, FIG. 6A or FIG. 7A share one evaporation aperture, that is, each evaporation aperture 801 is in the form of K4. After corresponding rotation, the mask for making the second sub-pixel group 202 in the pixel structure shown in FIG. 5A, FIG. 6A or FIG. 7A may be turned into the mask for making the second sub-pixel group 202 in the pixel structure shown in FIG. 5B, FIG. 6B or FIG. 7B. The manner that two or four sub-pixels share one evaporation aperture enables to reduce the space occupation and increase the aperture ratio to enhance the PPI, or enlarge the apertures of the existing mask without increasing the number of the apertures, thereby facilitating reduction of the process difficulty.

It should be noted that, the second sub-pixel groups 202 in the pixel structures shown in FIG. 2A to FIG. 7B are all second-type sub-pixel groups defined in the preset disclosure. When a first-type sub-pixel group in a pixel structure is exactly identical with a region defined by two side-by-side second sub-pixels of the second sub-pixel group 202 in the pixel structure in shape and size, the mask for making the second sub-pixel group 202 of the pixel structure can also be used to make each first-type sub-pixel group in the pixel structure, thereby saving the costs. Moreover, by means of an offset of mask and a corresponding evaporation, the mask for making the second sub-pixels 202 in the pixel structures shown in FIG. 2A to FIG. 4B can also be used to make the second sub-pixels 202 in the pixel structures shown in FIG. 5A to FIG. 7B to simplify a mask manufacturing process.

In other exemplary embodiments of the present disclosure, a mask for making sub-pixel groups of a same color in the pixel structure may also be in the form shown in FIG. 8B, which has a plurality of staggered evaporation apertures 801, the shape and size of each aperture 801 being identical with the aperture of the mask shown in FIG. 8A, but a total number of the evaporation apertures 801 being less than that of the evaporation apertures of the mask shown in FIG. 8A. For example, when the mask shown in FIG. 8B is used to make second sub-pixel groups, these evaporation apertures 801 of the mask merely correspond to some of the second sub-pixel groups 202 shown in FIG. 2A to FIG. 7B. Therefore, when the mask is used to make all of the second sub-pixel groups in the pixel structures, it is required to perform evaporation in an offset manner for at least twice. Because the evaporation apertures 801 of the mask shown in FIG. 8B are staggered, the strength of the FMM is able to be enhanced, the problems such as warping and fracture of the FMM are able to be avoided as much as possible, and the defects affecting the evaporation quality such as dizzy and offset of the evaporation film are able to be reduced.

In other exemplary embodiments of the present disclosure, a common mask may also be used for evaporation to make each sub-pixel of the first type and each sub-pixel of the second type. Evaporation apertures of the masks used for making the two types of sub-pixels are different in size. In addition, because each sub-pixel of the first type is elongated, an evaporation aperture of the mask corresponding to a sub-pixel of the first type is larger than an evaporation aperture of the mask corresponding to a sub-pixel of the second type. For example, the length of an evaporation aperture of the mask corresponding to a sub-pixel of the first type is equal to the sum of lengths of two sub-pixels of the second type and the length of a gap between the two sub-pixels. Therefore, the mask corresponding to the sub-pixels of the first type has a higher strength, and a lower difficulty of manufacturing process.

Moreover, it should be noted that, the arrangement of the four sub-pixel groups in each pixel group of the present disclosure is not limited to the rectangular form of two rows and two columns in the foregoing exemplary embodiments, and may also be other forms than the array of two rows and two columns. For example, the four sub-pixel groups are arranged in a column or a row; or the four sub-pixel groups are arranged in two misaligned columns; or three of the four sub-pixel groups are arranged around one of the four sub-pixel groups. The arrangement of all pixel groups is also not limited to the array mode in the foregoing exemplary embodiments, and may be adaptively changed according to the arrangement of the four sub-pixel groups, to realize an arrangement of a regular form.

To sum up, in the pixel structures of exemplary embodiments of the present disclosure, each pixel group includes four sub-pixel groups of different colors, enabling to enhance the luminosity, reduce the power consumption, as well as enlarge the color gamut and achieve a better display effect; At least two side-by-side sub-pixels in a sub-pixel group having two or more sub-pixels are able to share one evaporation aperture, thereby enabling to lower the manufacturing difficulty of masks, increase the process allowance, and facilitate achievement of a high PPI. Moreover, not all of the four sub-pixel groups in each pixel group include an identical number of sub-pixels, and each sub-pixel of a sub-pixel group having a minimum number of sub-pixels is shared. Therefore, spatial utilization is able to be further enhanced, thus enable to further enhance the pixel aperture ratio and achieve a high PPI and resolution.

An exemplary embodiment of the present disclosure also provides a display device, including above pixel structures. The display device may be any product or component having a display function such as an OLED panel, a mobile phone, a tablet computer, a television, a display, a notebook computer, a digital photo frame, and a navigator, etc. Since the display device of the present disclosure includes the above pixel structures, the display device has a high display uniformity and good display quality.

The above exemplary embodiments have describled the present disclosure in detail. However, it should be understood that, the above description are merely describe the preferred exemplary embodiments, which is not tend to limit the protection scope of the present disclosure. Any changes or modifications made by those of ordinary skilled in the art according to the above disclosure all fall within the protection scope of the appended claims.

What is claimed is:

1. A pixel structure, comprising:
a plurality of pixel groups, each pixel group having four sub-pixel groups, the four sub-pixel groups having different colors from each other, not all of the four sub-pixel groups comprising an identical number of sub-pixels, each sub-pixel in a sub-pixel group having a minimum number of sub-pixels being shared.

2. The pixel structure of claim 1, wherein the four sub-pixel groups in each pixel group are classified into first-type sub-pixel groups and second-type sub-pixel groups, wherein the first-type sub-pixel group has a minimum number of sub-pixels, which is one or two, and the sub-pixels in each of the first-type sub-pixel groups are arranged in a same manner, a number of the sub-pixels in the second-type sub-pixel group is twice a number of the sub-pixels in the first-type sub-pixel group, and the sub-pixels in each of the second-type sub-pixel groups are arranged in a same manner.

3. The pixel structure of claim 2, wherein all of the sub-pixels in the first-type sub-pixel group are identical in shape and size, and all of the sub-pixels in the second-type sub-pixel group are identical in shape and size.

4. The pixel structure of claim 3, wherein each of the sub-pixels in each pixel group has a shape of a rectangle; a width of a rectangle corresponding to a sub-pixel in the first-type sub-pixel group is equal to a width of a rectangle corresponding to a sub-pixel in the second-type sub-pixel group; and a length of a rectangle corresponding to a sub-pixel in the first-type sub-pixel group is equal to a sum of lengths of rectangles of two adjacent sub-pixels in the second-type sub-pixel group and a gap between the two adjacent sub-pixels.

5. The pixel structure of claim 1, wherein colors of the four sub-pixel groups in each pixel group are red, green, blue, and a fourth color respectively, wherein the fourth color is a color different from red, green, and blue.

6. The pixel structure of claim 2, wherein in each pixel group, when each first-type sub-pixel group includes one sub-pixel, each second-type sub-pixel group includes two sub-pixels arranged in two rows and one column or arranged in two columns and one row, and the two sub-pixels in the second-type sub-pixel group are arranged along a length direction of the sub-pixel in the first-type sub-pixel group; or in each pixel group, when each first-type sub-pixel group includes two sub-pixels, each second-type sub-pixel group includes four sub-pixels arranged in an array of two rows and two columns, and the two sub-pixels in the first-type sub-pixel group are arranged in two rows and one column or arranged in two columns and one row.

7. The pixel structure of claim 2, wherein two of the four sub-pixel groups in each pixel group are first-type sub-pixel groups, and the two first-type sub-pixel groups are arranged side by side or diagonally.

8. A mask for manufacturing the pixel structure according to claim 1.

9. The mask of claim 8, wherein a size of one evaporation aperture of the mask corresponds to a sum of sizes of at least two sub-pixels of a same color in a pixel group of the pixel structure having two or more sub-pixels.

10. A display device, comprising the pixel structure according to claim 1.
